(19) United States
(12) Patent Application Publication
(10) Pub. No.: US 2024/0104273 A1
(43) Pub. Date: Mar. 28, 2024

(54) VERIFICATION SYSTEM, VERIFICATION METHOD, AND VERIFICATION PROGRAM

(71) Applicant: NEC Corporation, Minato-ku, Tokyo (JP)

(72) Inventor: Noritaka Yamashita, Tokyo (JP)

(73) Assignee: NEC Corporation, Minato-ku, Tokyo (JP)

(21) Appl. No.: 18/275,560

(22) PCT Filed: Feb. 12, 2021
(86) PCT No.: PCT/JP2021/005213

§ 371 Date: Aug. 2, 2023

(51) Int. Cl. G06F 30/27

(52) U.S. Cl. CPC G06F 30/27

(57) ABSTRACT

The surrogate model construction means 81 constructs a surrogate model that simulates behavior of an analysis target, using operation data of the analysis target as training data. The surrogate model selection means 82 selects the surrogate model that is judged to best reproduce the behavior of the analysis target by the operation data according to verification contents, under specified condition, from the operation data of the analysis target. The verification means 83 verifies the analysis target using the selected surrogate model.

### TECHNICAL FIELD

This invention relates to a verification system, a verification method, and a verification program that performs verification using a surrogate model.

### BACKGROUND ART

In recent years, verification using simulation has been used in development to reduce the burden of verification processes and to control the occurrence of rework. For example, MDB (Model-Based Development) is being used in automotive design and development, and simulations such as SILS (Software In the Loop Simulation), RCP (Rapid Control Prototyping), and HILS (Hardware In the Loop Simulation) are being used.

Another known method to speed up simulation is to use surrogate models. The surrogate model is an alternative model for evaluation by simulation and are used to derive approximate solutions at high speed. For example, Patent literature 1 describes product design and simulation using surrogate models.

### CITATION LIST

### Patent Literature

PL 1: Japanese Laid-Open Paten Publication No. 2016-146169

### SUMMARY OF INVENTION

### Technical Problem

For example, in automotive design and development as described above, verification is performed by repeating simulations, but for large-scale systems, the time and computational cost of simulation are generally enormous. Therefore, by using a surrogate model as an alternative to simulation, it is possible to reduce the computational cost of the verification process.

On the other hand, since an automobile consists of a large number of units/software, it is necessary to build and combine simulations of each unit and software when conducting coupling tests, etc. It is possible to reduce the cost of the analysis itself in the verification process by using the surrogate model described in Patent literature 1.

However, when performing a coupling test by combining a large number of units as described above, it is necessary to appropriately combine the surrogate models of each unit for verification and perform the analysis. This results in an increase in the amount of work required in the preliminary stage of analysis, which in turn increases the cost of the verification process.

In addition, as the number of analysis targets increases, the types of surrogate models used also increase. Therefore, when there are many surrogate models for each of the many units, selecting a surrogate model suitable for the analysis is still very costly. Therefore, it is desirable to be able to reduce the cost of the verification process even when a surrogate model is used for verification in situations where verification using simulation is necessary.

Therefore, it is an exemplary object of the present invention to provide a verification system, a verification method, and a verification program that can reduce the cost of the verification process using surrogate models.

### Solution to Problem

The verification system according to the present invention includes a surrogate model construction means which constructs a surrogate model that simulates behavior of an analysis target, using operation data of the analysis target as training data, a surrogate model selection means which selects the surrogate model that is judged to best reproduce the behavior of the analysis target by the operation data according to verification contents, under specified condition, from the operation data of the analysis target, and a verification means which verifies the analysis target using the selected surrogate model.

The verification method according to the present invention includes: constructing a surrogate model that simulates behavior of an analysis target, using operation data of the analysis target as training data; selecting the surrogate model that is judged to best reproduce the behavior of the analysis target by the operation data according to verification contents, under specified condition, from the operation data of the analysis target; and verifying the analysis target using the selected surrogate model.

The verification program according to the present invention causing a computer to execute: a surrogate model construction process of constructing a surrogate model that simulates behavior of an analysis target, using operation data of the analysis target as training data; a surrogate model selection process of selecting the surrogate model that is judged to best reproduce the behavior of the analysis target by the operation data according to verification contents, under specified condition, from the operation data of the analysis target; and a verification process of verifying the analysis target using the selected surrogate model.

### Advantageous Effects of Invention

According to the present invention, it is possible to reduces the cost of the verification process using surrogate models.

### BRIEF DESCRIPTION OF DRAWINGS

FIG. 1 It depicts a block diagram illustrating a configuration example of the first exemplary embodiment of the verification system of according to the present invention.

FIG. 2 It depicts a block diagram illustrating a configuration example of a verification unit of the first exemplary embodiment.

FIG. 3 It depicts a flowchart illustrating an example of the operation of the verification system of the first exemplary embodiment.

FIG. 4 It depicts a flowchart illustrating an example of the operation of the verification unit of the first exemplary embodiment.

FIG. 5 It depicts a block diagram illustrating a configuration example of the second exemplary embodiment of the verification system of according to the present invention.

FIG. 6 It depicts a block diagram illustrating a configuration example of a verification unit of the second exemplary embodiment.

FIG. 7 It depicts a flowchart illustrating an example of the operation of the verification unit of the second exemplary embodiment.

FIG. 8 It depicts a block diagram illustrating a configuration example of the third exemplary embodiment of the verification system of according to the present invention.

FIG. 9 It depicts an explanatory diagram illustrating an example of a visualization of the surrogate model for each unit.

FIG. 10 It depicts a block diagram illustrating a configuration example of a verification unit of the third exemplary embodiment.

FIG. 11 It depicts a flowchart illustrating an example of the operation of the verification unit of the third exemplary embodiment.

FIG. 12 It depicts a block diagram showing an overview of the verification system according to the present invention.

### DESCRIPTION OF EMBODIMENTS

Hereinafter, exemplary embodiments of the present invention will be described with reference to the drawings.

### Exemplary Embodiment 1

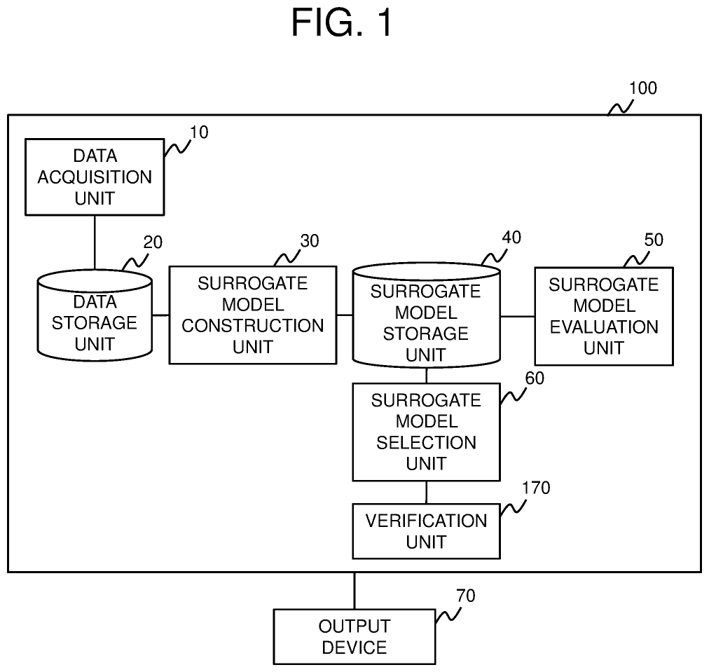

FIG. 1 is a block diagram illustrating a configuration example of the first exemplary embodiment of the verification system of according to the present invention. The verification system 100 of this exemplary embodiment is a system that verifies an analysis target using a surrogate model. Since the surrogate model described above can be said to be a model that enables refinement of approximate solutions, the verification system 100 in this exemplary embodiment can be said to be a system that performs verification using a surrogate model that enables refinement of approximate solutions.

The verification system 100 of this exemplary embodiment includes a data acquisition unit 10, a data storage unit 20, a surrogate model construction unit 30, a surrogate model storage unit 40, a surrogate model evaluation unit 50, a surrogate model selection unit 60, and a verification unit 170. The verification system 100 is connected to an output device 70 that outputs various processing results.

The output device 70 is realized, for example, as a display device or a printer. The output device 70 may also be realized as a control device that outputs control information according to the processing results to each unit.

The data acquisition unit 10 acquires data used by the verification system 100 for various processes and stores them in the data storage unit 20. The following description assumes a situation in which the verification system 100 is used in automobile design and development. That is, in this exemplary embodiment, it is assumed that the verification system 100 is used in situations where the operating state of an automobile is verified or where a defect occurs is verified.

However, the target for which the verification system 100 is used is not limited to automobile design and development, but may be, for example, the design and development of motorcycles or various control devices.

The data acquisition unit 10 specifically acquires operation data to be analyzed and verification data. In the case of an automobile, the operation data to be analyzed includes the automobile's driving data and data at the time of a defect, while the verification data includes the automobile's normal data. The details of the operation data are described below.

The data acquisition unit 10 may, for example, receive various data collected by the connected car, such as vehicle status and surrounding road conditions, as driving data.

The data acquisition unit 10 stores the operation data and verification data to which identification information identifying the analysis target is added in the data storage unit 20. For example, if the acquired data does not contain identification information, the data acquisition unit 10 adds the identification information to the acquired data and stores it in the data storage unit 20.

In this exemplary embodiment, information that identifies a unit, which is the smallest unit of verification, and information that identifies a domain, which is a grouping of multiple units are assumed as the identification information. The contents of each unit to be grouped into a domain are arbitrary, and are set in advance by the designer or others and stored in the data storage unit 20. The following is a specific explanation of how domains are set up in the case of automobile design.

The first method of setting up a domain is to set up a domain for each function of an automobile. Automobile functions include, for example, control systems, body systems, safety systems, and information systems. The control systems include those that control basic automobile functions such as the engine and brakes, i.e., engine control, idling stop control, and gear shift control. The body systems are those that are not directly involved in driving but are related to automobiles, such as air conditioners, headlamps, electronic keys, electronic mirrors, etc.

The safety systems are those that ensure safety during driving, such as airbags, ADAS (Advanced Driver-Assistance Systems)/automatic driving systems, brake control, and steering control. The information systems are those related to so-called infotainment in automobiles, and include, for example, car navigation systems, communication units between in-vehicle communication devices, and communication units between in-vehicle devices and communication devices used by the driver.

The second method of setting the domain is to set the domain according to the proximity of the physical location. Examples of targets near the location include near the engine compartment, under the body, on the ceiling, and near the rear.

The third method of setting up a domain is based on wiring. For example, since multiple buses are used in automobiles, such as LIN (Local Interconnect Network) and CAN (Controller Area Network), units connected to each bus may be grouped together as one domain.

The fourth setting method is to make each bus unit connected to the CGW (Central Gateway), which relays communications performed between multiple ECUs (Electronic Control Units), a single domain.

These setting methods are examples, and each unit that performs a series of operations may be grouped together and set up as a single domain.

Automobile operation data includes, for example, the unit in operation, the version of software used, and input/output parameter information. The operation data can be classified, for example, into data for unit tests and data for coupling tests. Data for unit tests may include, for example, information on other units to be connected.

Vehicle driving data includes information such as position and speed acquired by GPS (Global Positioning System), video data during driving, and information acquired by various sensors such as Lidar (light detection and ranging).

Other data on the occurrence of the defect may include information obtained directly from the automobile, as well as reports interviewed from drivers at dealerships and other locations.

The data storage unit 20 stores the operation data and verification data described above, as well as information indicating the contents of the units included in each domain. The data storage unit 20 is realized by, for example, a magnetic disk.

The surrogate model construction unit 30 constructs a surrogate model that simulates behavior of an analysis target using the operation data of the analysis target as training data. In this exemplary embodiment, the surrogate model construction unit 30 constructs a surrogate model for each unit or domain.

Specifically, the surrogate model construction unit 30 acquires learning data from the data acquisition unit 10 for each unit or domain of the analysis target identified based on the identification information. Then, the surrogate model construction unit 30 constructs a surrogate model for each analysis target by machine learning using the acquired learning data.

In particular, the surrogate model construction unit 30 constructs a surrogate model for each domain unit that summarizes each unit, eliminating the need to combine simulators for each unit and software in the coupling test, thereby reducing the cost of the verification process.

For example, when verifying the coupling of multiple units in a general way, it is necessary to prepare models and actual equipment for them. Also, when combining these multiple models, the selection of models is complicated. On the other hand, in this exemplary embodiment, the surrogate model construction unit 30, for example, constructs a surrogate model for each domain set based on the wiring as described above. This eliminates the need to combine simulators and surrogate models for individual units connected to each bus, thus reducing the cost of the verification process.

In addition, the surrogate model construction unit 30 may generate surrogate models for each condition. The conditions are predetermined by the designer or others, for example, the region, time, and environment in which the training data was acquired.

The method by which the surrogate model construction unit 30 generates the surrogate model is arbitrary. For example, the surrogate model construction unit 30 may construct a surrogate model using the method described in Patent literature 1, or may construct a surrogate model using other known techniques. The surrogate model construction unit 30 stores the constructed surrogate model in the surrogate model storage unit 40.

The surrogate model storage unit 40 stores the surrogate model. The surrogate model storage unit 40 may store not only surrogate models generated by the surrogate model construction unit 30, but also surrogate models generated by other devices (not shown) or the like. The surrogate model storage unit 40 is realized by, for example, a magnetic disk.

The surrogate model evaluation unit 50 evaluates the accuracy of the constructed surrogate model. The method of evaluating the surrogate model is arbitrary. For example, the surrogate model evaluation unit 50 may evaluate the accuracy of the surrogate model based on the error in reproducing the original data with the constructed surrogate model.

The following is an example of evaluating the accuracy of a surrogate model through cross-validation. For example, it is assumed that in a surrogate model, output F is obtained from parameters A to E. For example, in the case of a surrogate model that reproduces the behavior of a car engine, the parameters are, for example, the timing and amount of fuel injection, pressure, frequency, and interval, and the output is, for example, fuel consumption and displacement. The parameters A to E are the optimal solutions when the value of output F is good. First, multiple data sets of pairs of parameters A to E and their output F are prepared, and this data is divided into two groups: one for training and the other for verification.

Next, the surrogate model construction unit 30 constructs a surrogate model by learning using a set of data for training. The surrogate model evaluation unit 50 applies the parameters A to E for verification to the constructed surrogate model to obtain the output F′. The surrogate model evaluation unit 50 then calculates the error F^{˜} (^{˜} is a superscript tilde) between the obtained output F′ and the original value F for each group of verification data. The surrogate model evaluation unit 50 may, for example, calculate predetermined verification values (e.g., sum or average) from the obtained error F^{˜} and evaluate accuracy based on whether the calculated verification values meet predetermined criteria.

If the accuracy is evaluated as insufficient (e.g., does not meet predetermined criteria), the surrogate model evaluation unit 50 may instruct the surrogate model construction unit 30 to reconstruct the surrogate model. In this case, the surrogate model construction unit 30 may reconstruct the surrogate model by adding training data or tuning the parameters (hyperparameters) during construction.

The surrogate model selection unit 60 accepts input of data for the analysis target and selects a surrogate model that is highly relevant to that analysis target. Specifically, the surrogate model selection unit 60 selects, from the operation data of the analysis target, a surrogate model that is judged to best reproduce the behavior of the analysis target by the operation data according to the verification contents under the specified conditions.

Various methods can be used to determine the method that best reproduces the behavior of the analysis target. The following are examples of judgment methods. However, the method of selecting a surrogate model that is highly relevant to the analysis target is not limited to the judgment methods illustrated below.

The first method of judgment is to select a surrogate model whose input/output data items match the data items to be analyzed. This is because a surrogate model that has been trained to obtain the desired output values from the input data can be judged to best reproduce the behavior of the analysis target.

In cases where there are multiple surrogate models with matching input/output data items, the first method of judgment is to select a surrogate model that is close to the setting environment in the simulation and the measurement environment to be analyzed. The measurement environment includes, for example, temperature, weather, road surface conditions, and other surrounding information. The closer the assumed environment is, the more likely it is to reproduce the behavior of the analysis target.

The third method of judgment is to select a surrogate model that has a small error between the simulation results and output values of interest. In a surrogate model, multiple output values are obtained, but the error in each output value is biased. This is because a surrogate model constructed by focusing on the parameter of interest is judged to better reproduce the behavior of the analyte of interest.

The fourth method of judgment is to select a surrogate model with the smallest error during verification. For example, a pair of input data and output data is prepared from the operation data to be analyzed. Then, when the input data is applied to the surrogate model to obtain output values, the surrogate model with the smallest error between the output values and the output data may be selected.

The fifth method of judgment is to select a surrogate model that has close characteristics between the data items of the operation data to be analyzed and the data set used during construction. The information representing the characteristics includes, for example, statistical information (mean and variance), correlation values of inputs and outputs, and correlations between specific parameters. For example, if the operation data of an analysis target seeks to reproduce the operating conditions at a lower temperature, it is determined that selecting a surrogate model that has been trained using more operation data acquired at a lower temperature will better reproduce the behavior of the analysis target of interest.

The verification unit 170 verifies the analysis target using the selected surrogate model. The verification details are assumed to include the verification of the operation of the analysis target, the verification of the parameters used to operate the analysis target, and a situation in which a defect of the analysis target is verified. In the first exemplary embodiment, the case in which the verification unit 170 verifies the operation of the analysis target and parameters are described.

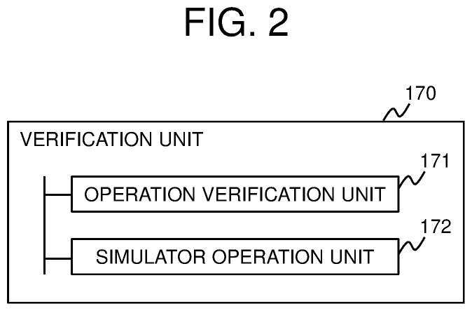

FIG. 2 is a block diagram illustrating a configuration example of a verification unit 170 of this exemplary embodiment. The verification unit 170 of this exemplary embodiment includes an operation verification unit 171 and a simulator operation unit 172.

The operation verification unit 171 performs verification processing of the operation of the analysis target and parameters using the selected surrogate model. Specifically, the operation verification unit 171 inputs operation data including parameters used in operating the analysis target, applies the input parameters to the selected surrogate model to calculate evaluation values.

The operation verification unit 171 repeats this verification process up to a predetermined condition, and identifies the best parameter as the verification result based on the obtained evaluation value. The operation verification unit 171 may, for example, take the parameter corresponding to the most favorable evaluation value as the verification result. The operation verification unit 171 may, for example, repeat the verification process until the assumed pattern of parameters is covered, or may repeat the verification process for a predetermined number of times until the desired evaluation value is obtained.

The operation verification unit 171 then outputs the verification results. In addition to the optimal parameters at the time of verification, the operation verification unit 171 may also output the evaluation value when the parameters are applied, information on the surrogate model used, etc.

The general method of executing such a verification process each time using a simulator takes a lot of time. On the other hand, in this exemplary embodiment, the operation verification unit 171 performs the verification process for the analysis target using the selected surrogate model. This reduces the cost of the verification process, since evaluation values can be obtained simply by applying parameters to the surrogate model.

The simulator operation unit 172 applies the verification results obtained by the operation verification unit 171 to the simulator to obtain operation results. As described above, by using a surrogate model, an approximation of the optimal parameters can be obtained. Therefore, the simulator operation unit 172 operates the simulator based on the obtained approximate values to derive the optimal values of parameters with higher accuracy. The simulator is prepared in advance according to the analysis target.

Thus, the simulator operation unit 172 derives optimal values of parameters by operating the simulator based on the verification results derived by the surrogate model. Therefore, compared to the case where all verification is performed using a simulator, it is possible to obtain highly accurate optimal values while reducing costs.

If the verification results by the operation verification unit 171 are used as is, the verification unit 170 does not need to include the simulator operation unit 172.

The following describes the operation of the verification unit 170 when the engine of a vehicle is the analysis target, using specific examples. It is assumed that a surrogate model that simulates the behavior of the vehicle's engine has been selected by the surrogate model selection unit 60 as a precondition for verification by the verification unit 170.

The operation verification unit 171 inputs the operation data to be analyzed and applies it to the parameters of the surrogate model. The input parameters (control parameters) include the fuel injection timing (e.g., [0, 2, 4]), amount (e.g., 10 L), pressure, frequency, and interval as well as the control software version (e.g., Eng-003) described above. The operation verification unit 171 then outputs the evaluation value when the parameters are applied. Examples of control items that indicate output values include fuel consumption (km/L), displacement (cm³), power output, RPM, and temperature.

If an appropriate control item is obtained (e.g., fuel consumption is below a predetermined value, etc.), the operation verification unit 171 outputs the parameters at that time as optimal values.

The simulator operation unit 172 applies the verification results (optimal values) obtained by the operation verification unit 171 to the simulator to derive more accurate evaluation values. For example, if the injection timing (e.g., [0, 2, 4]) and amount (e.g., 10 L) described above are output as verification results, the simulator operation unit 172 applies these verification results to the simulator to obtain more accurate evaluation values (e.g., fuel consumption (km/L) and displacement (cm³)).

The data acquisition unit 10, the surrogate model construction unit 30, the surrogate model evaluation unit 50, the surrogate model selection unit 60, and the verification unit 170 (more specifically, the operation verification unit 171 and the simulator operation unit 172) are realized by a computer processor (for example, CPU (Central Processing Unit)) that operates according to a program (verification program).

For example, a program may be stored in a storage unit (not shown) of the verification system, and the processor may read the program and operate according to the program as the data acquisition unit 10, the surrogate model construction unit 30, the surrogate model evaluation unit 50, the surrogate model selection unit 60, and the verification unit 170. The functions of the verification system 100 may be provided in a SaaS (Software as a Service) format.

Each of the data acquisition unit 10, the surrogate model construction unit 30, the surrogate model evaluation unit 50, the surrogate model selection unit 60, and the verification unit 170 (more specifically, the operation verification unit 171 and the simulator operation unit 172) may be realized by dedicated hardware. Some or all of the components of each device may be realized by general-purpose or dedicated circuit (circuitry), processors, etc., or a combination thereof. They may be configured by a single chip or by multiple chips connected through a bus. Some or all of the components of each device may be realized by a combination of the above-mentioned circuit, etc. and a program.

When some or all of the components of the verification system 100 are realized by multiple information processing devices, circuits, etc., the multiple information processing devices, the circuit, etc. may be arranged in a centralized or distributed manner. For example, the information processing devices, circuits, etc., may be realized as a client-server system, a cloud computing system, or the like, each of which is connected through a communication network.

The surrogate model storage unit 40, the surrogate model evaluation unit 50, the surrogate model selection unit 60, and the verification unit 170 perform verification using surrogate models. Therefore, the device including the surrogate model storage unit 40, the surrogate model evaluation unit 50, the surrogate model selection unit 60, and the verification unit 170 can be called a verification device.

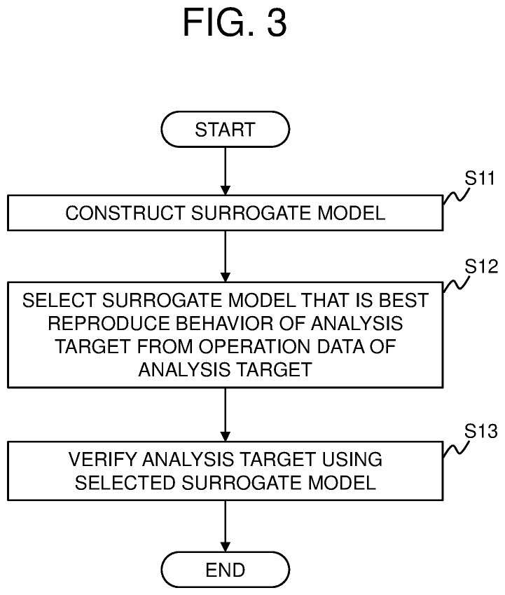

Next, the operation of verification system 100 of this exemplary embodiment will be described. FIG. 3 is a flowchart illustrating an example of the operation of the verification system of this exemplary embodiment. The surrogate model construction unit 30 constructs a surrogate model that simulates behavior of an analysis target, using operation data of the analysis target as training data (step S11). The surrogate model selection unit 60 selects the surrogate model that is judged to best reproduce the behavior of the analysis target by the operation data according to verification contents under specified conditions, from the operation data of the analysis target (Step S12). The verification unit 170 then verifies the analysis target using the selected surrogate model (step S13).

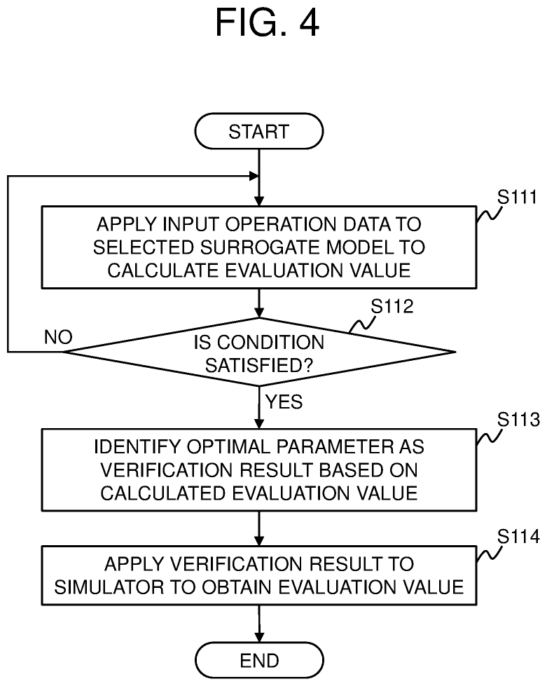

FIG. 4 is a flowchart illustrating an example of the operation of the verification unit 170 of this exemplary embodiment. The operation verification unit 171 inputs operation data including a parameter used in operating the analysis target, and applies the input parameters to the selected surrogate model to calculate evaluation values (step S111). The operation verification unit 171 determines whether the predetermined conditions are satisfied (step S112). If the condition is not satisfied (No in step S112), the operation verification unit 171 repeats the process of step S111.

On the other hand, if the condition is satisfied (Yes in step S112), the operation verification unit 171 identifies the optimal parameters as a verification result based on the calculated evaluation values (step S113). The simulator operation unit 172 applies the obtained verification result by the operation verification unit 171 to a simulator to obtain the evaluation values (step S114). The final parameters are then determined based on the obtained evaluation values.

As described above, in this exemplary embodiment, the surrogate model construction unit constructs a surrogate model using the operation data of the analysis target as training data, and the surrogate model selection unit 60 selects the surrogate model from the operation data of the analysis target according to the verification contents under specified conditions. Then, the verification unit 170 verifies the analysis target using the selected surrogate model. Thus, the cost of the verification process using the surrogate model can be reduced.

Additionally, in this exemplary embodiment, the operation verification unit 171 of the verification unit 170 inputs the operation data to be analyzed and applies the input operation data to the surrogate model to calculate the evaluation values. The operation verification unit 171 identifies the optimal parameters as verification results based on the calculated evaluation values. Then, the simulator operation unit 172 applies the verification results obtained by the operation verification unit 171 to the simulator for the analysis target to obtain the operation results. Thus, it is possible to obtain more accurate output values while reducing the cost of the verification process.

### Exemplary Embodiment 2

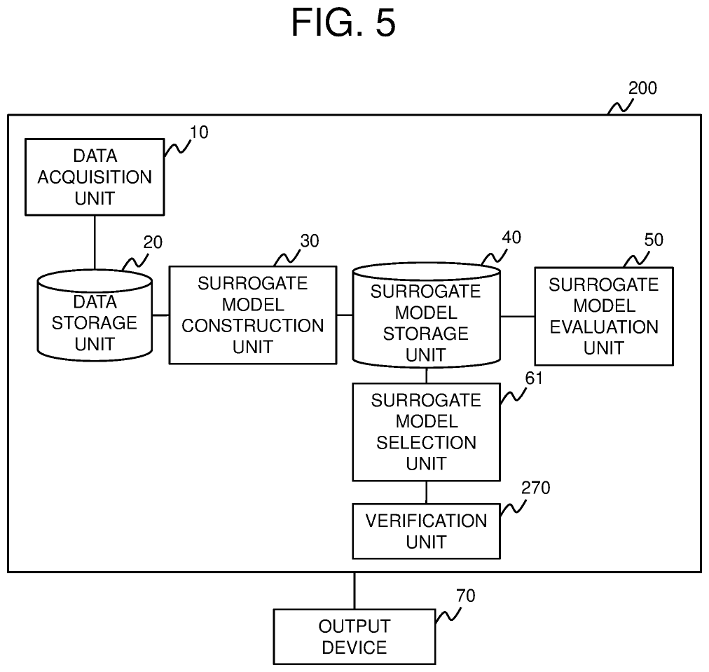

Next, a second exemplary embodiment of the verification system of the present invention will be described. The second exemplary embodiment shows the configuration of the verification system of the present invention when it is used to verify defects in the analysis target. FIG. 5 is a block diagram illustrating a configuration example of the second exemplary embodiment of the verification system of according to the present invention.

The verification system 200 in this exemplary embodiment includes a data acquisition unit 10, a data storage unit 20, a surrogate model construction unit 30, a surrogate model storage unit 40, a surrogate model evaluation unit 50, a surrogate model selection unit 61, and a verification unit 270.

In other words, the configuration of the verification system 200 in this exemplary embodiment differs from that of the first exemplary embodiment illustrated in FIG. 1 in that it includes the surrogate model selection unit 61 instead of the surrogate model selection unit 60 and the verification unit 270 instead of the verification unit 170. Otherwise, the configuration is the same as in the first exemplary embodiment.

The surrogate model selection unit 61 accepts input of data to be analyzed and selects a surrogate model that is highly relevant to the analysis target. The surrogate model selection unit 61 in this exemplary embodiment accepts input of data at the time of occurrence of a defect as the data to be analyzed. The method of selecting a surrogate model that is highly relevant to the analysis target is the same as in the first exemplary embodiment.

Here, the surrogate model construction unit 30 constructs a surrogate model in a manner that can reproduce the original simulation to some extent. In other words, since the surrogate model simulates the behavior of the analysis target, if the surrogate model is highly accurate, it is considered possible to reproduce the situation when a defect occurs, even without direct data on the defect occurrence.

However, constructing a surrogate model using data from when the defect occurred is more desirable because it improves the reproducibility of the defect by the surrogate model and makes it easier to generate similar defects.

Since the situation of the defect occurrence and the environment (parameters) at the time of the surrogate model construction do not exactly match, there is a high possibility that errors may occur. Therefore, the surrogate model selection unit 61 may select multiple surrogate models that are highly relevant to the analysis target. The surrogate models selected here may be unit-based surrogate models or domain-based surrogate models. The surrogate model selection unit 61 may then have the verification unit 270, described below, perform verification using multiple surrogate models. By selecting multiple surrogate models in this manner, it is possible to obtain more valid evaluation values.

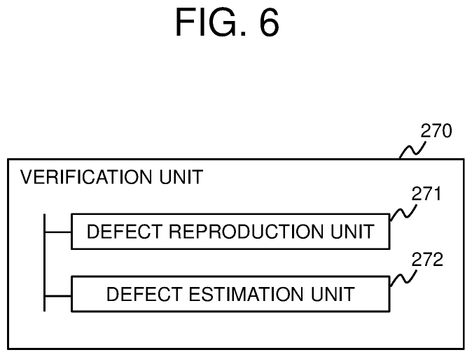

FIG. 6 is a block diagram illustrating a configuration example of a verification unit 270 of this exemplary embodiment. The verification unit 270 of this exemplary embodiment includes a defect reproduction unit 271 and a defect estimation unit 272.

The defect reproduction unit 271 reproduces the defect situation of the analysis target using the selected surrogate model. Specifically, the defect reproduction unit 271 inputs data at the time the defect occurred, including parameters when the defect occurred in the analysis target, and applies the input parameters to the selected surrogate model to calculate an evaluation value. Hereafter, the evaluation value calculated by the defect reproduction unit 271 is sometimes referred to as a first evaluation value. When multiple surrogate models are selected, the defect reproduction unit 271 calculates the evaluation values by each surrogate model.

the defect estimation unit 272 applies the normal condition data to the surrogate model used by defect reproduction unit 271 to reproduce the defect situation, and calculates the evaluation values under the normal condition. Hereafter, the evaluation value calculated using the normal data is sometimes referred to as a second evaluation value. The defect estimation unit 272 then compares the evaluation values calculated from the data at the time of the defect occurrence with the evaluation values calculated from the data at the time of normality to estimate the part of defect occurrence.

Normal data is data in which the items of the operation data (data during running) match or are close to each other and no abnormality occurs (not judged as abnormal), and the criteria for this are predetermined by the designer, etc. The method of estimating the part of defect occurrence is arbitrary, and the defect estimation unit 272 may, for example, estimate the part of defect occurrence based on whether or not the difference between the two evaluation values is within a predetermined range.

When multiple evaluation values are calculated by multiple surrogate models, the defect estimation unit 272 may compare the evaluation values calculated by each surrogate model to estimate the part of defect occurrence.

The data acquisition unit 10, the surrogate model construction unit 30, the surrogate model evaluation unit 50, the surrogate model selection unit 61, and the verification unit 270 (more specifically, the defect reproduction unit 271 and the defect estimation unit 272) are realized by a computer processor that operates according to a program (verification program).

Next, the operation of verification system 200 of this exemplary embodiment will be described. The operation of verification system of this exemplary embodiment is similar to the operation shown in the flowchart illustrated in FIG. 3. More specifically, the surrogate model selection unit 61 of this exemplary embodiment accepts input of data at the time of the defect as data to be analyzed. The verification unit 270 then verifies the analysis target using the selected surrogate model.

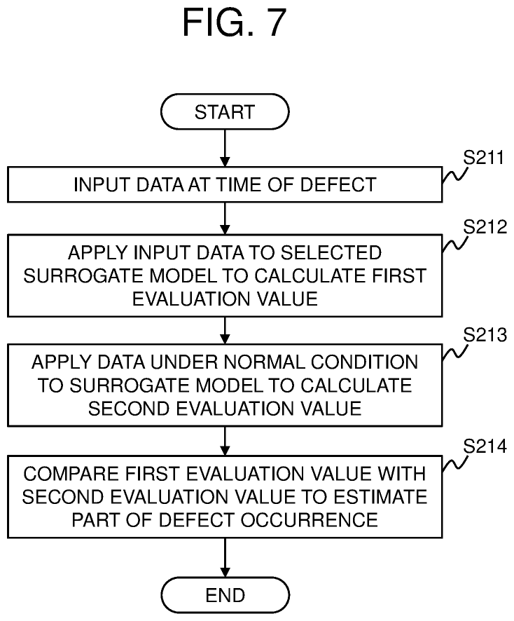

FIG. 7 is a flowchart illustrating an example of the operation of the verification unit 270 of this exemplary embodiment. The defect reproduction unit 271 inputs data at the time of defect, including a parameter when the defect occurred in the analysis target (step S211). The defect reproduction unit 271 then applies the input parameters to the selected surrogate model to calculate the first evaluation value (step S212). The defect estimation unit 272 applies the data under the normal condition to the surrogate model to calculate the second evaluation value (step S213). Then, the defect estimation unit 272 compares the first evaluation value with the second evaluation value to estimate the part of defect occurrence (step S214).

As described above, in this exemplary embodiment, the defect reproduction unit 271 of the verification unit 270 inputs parameters at the time of a defect occurrence, applies the input parameters to the selected surrogate model to calculate the first evaluation value. Then, the defect estimation unit 272 applies the data under the normal condition to the surrogate model to calculate the second evaluation value, and compares the first evaluation value with the second evaluation value to estimate the part of defect occurrence. Thus, the cost of the verification process can be reduced because the reproduction of the defect occurrence situation and the cause isolation can be performed simply.

In addition, for example, when trying to reproduce the situation using HILS (Hardware-In-the-Loop-Simulation) or the like when a defect occurs, there is a problem that it takes time to reproduce the situation because many units are involved. On the other hand, in this exemplary embodiment, surrogate models generated by domain units can be used, making it easy to verify which domain the defect occurred in.

### Exemplary Embodiment 3

Next, a third exemplary embodiment of the verification system of the present invention will be described. The third exemplary embodiment shows the configuration of the verification system of the present invention when it is used to verify the operation of an analysis target (in particular, unit-by-unit).

For example, each unit in an automobile is manufactured by Tier 1 and others. Although the specifications of these units, such as input/output, are known, the inside is often a black box. When performing operational verification on delivered parts, it is necessary to check whether they operate according to specifications and whether there are any defects that may occur in special cases. In such cases, a simulator may be utilized, but the problem is that the method of operation verification using only a simulator requires a lot of time. Therefore, the verification system of this exemplary embodiment can be used to simplify the operation verification.

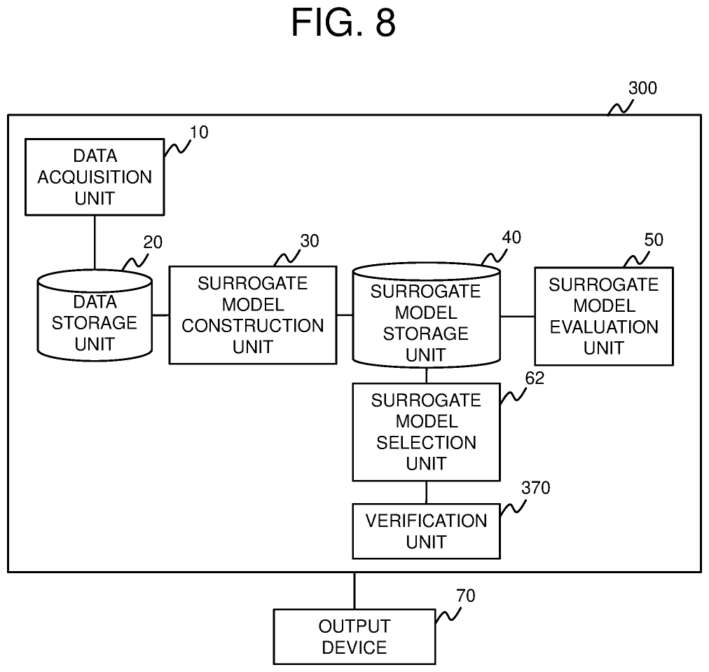

FIG. 8 is a block diagram illustrating a configuration example of the third exemplary embodiment of the verification system of according to the present invention. The verification system 300 of this exemplary embodiment includes a data acquisition unit 10, a data storage unit 20, a surrogate model construction unit 30, a surrogate model storage unit 40, a surrogate model evaluation unit 50, a surrogate model selection unit 62, and a verification unit 370.

In other words, the configuration of the verification system 300 in this exemplary embodiment differs from that of the first exemplary embodiment illustrated in FIG. 2 in that it includes the surrogate model selection unit 62 instead of the surrogate model selection unit 61 and the verification unit 370 instead of the verification unit 270. Otherwise, the configuration is the same as in the second exemplary embodiment.

The surrogate model selection unit 62 accepts input of data to be analyzed and selects a surrogate model that is highly relevant to the analysis target. The surrogate model selection unit 62 in this exemplary embodiment accepts input of unit operation data as the data to be analyzed. The method of selecting a surrogate model that is highly relevant to the analysis target is the same as in the first exemplary embodiment. In particular, in this exemplary embodiment, a unit-by-unit surrogate model is selected.

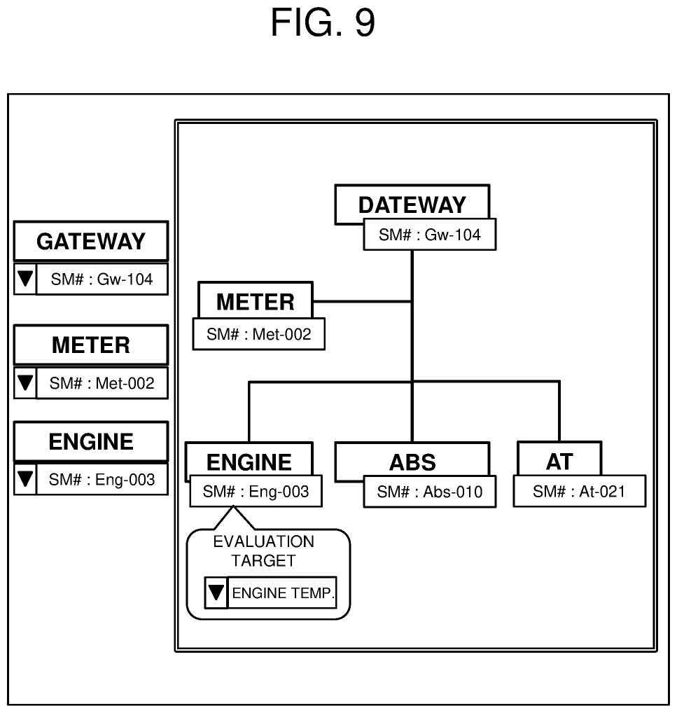

The output device 70 may visualize the combination of surrogate models for each unit used for verification. FIG. 9 is an explanatory diagram illustrating an example of a visualization of the surrogate model for each unit. FIG. 9 illustrates an example of a combination of surrogate models assuming the powertrain portion of an automobile. As illustrated in FIG. 9, the output device 70 may visualize the associated units (or domains) in relation to each other.

In addition, the output device 70 may accept designation of a surrogate model used for verification by a designer from a combination of visualized surrogate models. The example shown in FIG. 9 indicates that among the surrogate models for the engine, a surrogate model for evaluating engine temperature was selected. The surrogate model selection unit 62 may identify the surrogate model selected from the output device 70 as the surrogate model used for verification by the verification unit 370 described below.

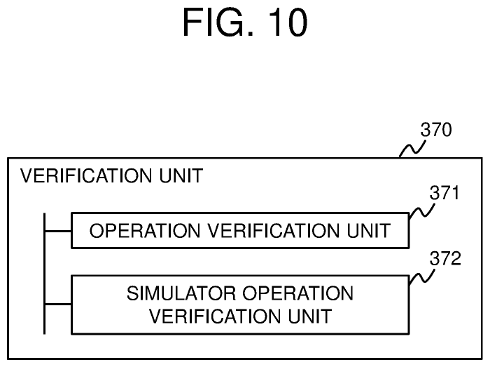

FIG. 10 is a block diagram illustrating a configuration example of a verification unit 370 of this exemplary embodiment. The verification unit 370 of this exemplary embodiment includes an operation verification unit 371 and a simulator operation verification unit 372.

The operation verification unit 371 verifies the operation of the analysis target using the selected surrogate model. Specifically, the operation verification unit 371 inputs evaluation data including the normal parameters of the analysis target, applies the input parameters to the selected surrogate model to calculate the evaluation value. Then, the operation verification unit 371 compares the calculated evaluation values with the evaluation values assumed in the evaluation data to verify whether or not a defect occurs.

The method of determining whether or not a defect occurs is arbitrary. For example, a method similar to the method by which the defect estimation unit 272 of the second exemplary embodiment estimates defects (e.g., whether the difference between the two evaluation values is within a predetermined range) may be used.

When a defect is estimated to occur based on the evaluation values, the simulator operation verification unit 372 verifies the operation using a simulator for the estimated defect part. The simulator is prepared in advance according to the analysis target. The method by which the simulator operation verification unit 372 verifies the operation is arbitrary. For example, the simulator operation verification unit 372 may apply the parameters used when the defect was estimated to occur to the simulator to obtain operation results. The simulator operation verification unit 372 may also obtain the operation results based on the parameters indicated by the designer, depending on the part of the estimated defect.

The data acquisition unit 10, the surrogate model construction unit 30, the surrogate model evaluation unit 50, the surrogate model selection unit 62, and the verification unit 370 (more specifically, the operation verification unit 371 and the simulator operation verification unit 372) are realized by a computer processor that operates according to a program (verification program).

Next, the operation of verification system 300 of this exemplary embodiment will be described. The operation of verification system of this exemplary embodiment is similar to the operation shown in the flowchart illustrated in FIG. 3. More specifically, the surrogate model selection unit 62 of this exemplary embodiment accepts input of unit-by-unit operation data as data to be analyzed. The verification unit 370 then performs verification of the unit-by-unit to be analyzed using the selected surrogate model.

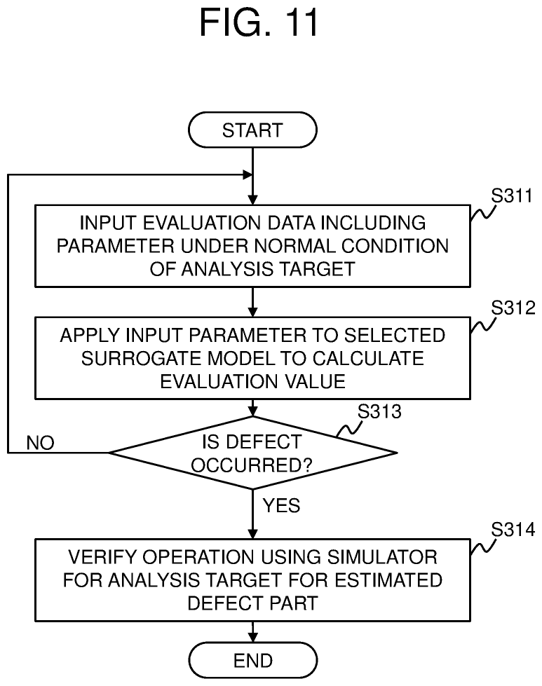

FIG. 11 is a flowchart illustrating an example of the operation of the verification unit of this exemplary embodiment. The operation verification unit 371 inputs evaluation data including a parameter under normal conditions of the analysis target (step S311). Then, the operation verification unit 371 applies the input parameter to the selected surrogate model to calculate an evaluation value (step S312). The operation verification unit 371 estimates whether or not a defect occurs based on the evaluation value (step S313).

If a defect is estimated not to have occurred (No in step S313), the process from step S311 is repeated. On the other hand, if a defect is estimated to have occurred (Yes in step S313), the simulator operation verification unit 372 verifies the operation using the simulator for the analysis target for the estimated defect part (step S314).

As described above, in this system, the operation verification unit 371 of the verification unit 370 inputs evaluation data including parameters in the normal state of the analysis target, applies the input parameters to the selected surrogate model, and calculates the evaluation values. If a defect is estimated to occur based on the evaluation values, the simulator operation verification unit 372 verifies the operation using the simulator for the analysis target for the estimated a part of the defect. Thus, the operation verification can be performed in a simplified manner, which reduces the cost of the verification process.

In other words, the verification unit 370 of this exemplary embodiment performs high-speed verification of normal data using a surrogate model, and when a defect is estimated to occur, the simulator is used to verify more detailed operating situation. In this way, the simulator is used only for verifications that require more accuracy, thus reducing the cost of the verification process.

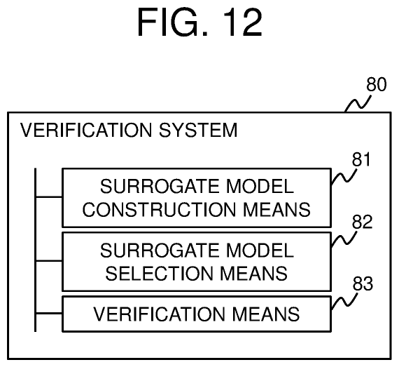

The following is an overview of the invention. FIG. 12 is a block diagram showing an overview of the verification system according to the present invention. The verification system 80 (e.g., verification system 100) according to the present invention includes a surrogate model construction means 81 (e.g., surrogate model construction unit 30) which constructs a surrogate model that simulates behavior of an analysis target (e.g., automobile), using operation data (e.g., driving data) of the analysis target as training data, a surrogate model selection means 82 (surrogate model selection unit 60) which selects the surrogate model that is judged to best reproduce the behavior of the analysis target by the operation data according to verification contents, under specified condition, from the operation data of the analysis target, and a verification means 83 (e.g., verification unit 170) which verifies the analysis target using the selected surrogate model.

Such a configuration can reduce the cost of the verification process using surrogate models.

The surrogate model construction means 81 may construct the surrogate model for each domain unit, which is the smallest unit of verification.

Specifically, the surrogate model construction means 81 may (for example, in the case of an automobile) construct the surrogate model for each domain unit that groups units by automobile function (e.g., control system, body system, safety system, information system, etc.).

The verification means 83 (e.g., verification unit 170) may include an operation verification means (e.g., operation verification unit 171) which inputs the operation data including a parameter used in operating the analysis target, applies the input parameters to the selected surrogate model to calculate an evaluation value, and identifies the optimal parameters as a verification result based on the calculated evaluation value, and a simulator operation means (e.g., simulator operation unit 172) which applies the obtained verification result to a simulator for the analysis target to obtain operating result.

The verification means 83 (e.g., verification unit 270) may include a defect reproduction means (e.g., defect reproduction unit 271) which inputs data at time of a defect, including a parameter when the defect occurred in the analysis target, and applies the input parameter to the selected surrogate model to calculate a first evaluation value, and a defect estimation means (e.g., defect estimation unit 272) which applies data under the normal condition to the surrogate model to calculate a second evaluation value, and compares the first evaluation value with the second evaluation value to estimate a part of the defect.

The verification means 83 (e.g., verification unit 370) may include an operation verification means (e.g., operation verification unit 371) which inputs evaluation data including a parameter under normal conditions of the analysis target, and applies the input parameter to the selected surrogate model to calculate an evaluation value, and a simulator operation verification means (e.g., simulator operation verification unit 372) which verifies, when a defect is estimated to occur based on the evaluation value, the operation using a simulator for the analysis target for an estimated part of the defect.

The surrogate model selection means 82 may select the surrogate model that matches a data item to be analyzed and an input/output data item.

A part of or all of the above exemplary embodiments may also be described as, but not limited to, the following supplementary notes.
(Supplementary note 1) A verification system comprising:
   a surrogate model construction means which constructs a surrogate model that simulates behavior of an analysis target, using operation data of the analysis target as training data;
   a surrogate model selection means which selects the surrogate model that is judged to best reproduce the behavior of the analysis target by the operation data according to verification contents, under specified condition, from the operation data of the analysis target; and a verification means which verifies the analysis target using the selected surrogate model.
(Supplementary note 2) The verification system according to Supplementary note 1, wherein
   the surrogate model construction means constructs the surrogate model for each domain unit, which is the smallest unit of verification.
(Supplementary note 3) The verification system according to Supplementary note 1 or 2, wherein
   the surrogate model construction means constructs the surrogate model for each domain unit that groups units by automobile function.
(Supplementary note 4) The verification system according to any one of Supplementary notes 1 to 3, wherein the verification means includes:
   an operation verification means which inputs the operation data including a parameter used in operating the analysis target, applies the input parameters to the selected surrogate model to calculate an evaluation value, and identifies the optimal parameters as a verification result based on the calculated evaluation value; and
   a simulator operation means which applies the obtained verification result to a simulator for the analysis target to obtain operating result.
(Supplementary note 5) The verification system according to any one of Supplementary notes 1 to 3, wherein the verification means includes:
   a defect reproduction means which inputs data at time of a defect, including a parameter when the defect occurred in the analysis target, and applies the input parameter to the selected surrogate model to calculate a first evaluation value; and
   a defect estimation means which applies data under the normal condition to the surrogate model to calculate a second evaluation value, and compares the first evaluation value with the second evaluation value to estimate a part of the defect.
(Supplementary note 6) The verification system according to any one of Supplementary notes 1 to 3, wherein the verification means includes:
   an operation verification means which inputs evaluation data including a parameter under normal conditions of the analysis target, and applies the input parameter to the selected surrogate model to calculate an evaluation value; and
   a simulator operation verification means which verifies, when a defect is estimated to occur based on the evaluation value, the operation using a simulator for the analysis target for an estimated part of the defect.
(Supplementary note 7) The verification system according to any one of Supplementary notes 1 to 6, wherein
   the surrogate model selection means selects the surrogate model that matches a data item to be analyzed and an input/output data item.
(Supplementary note 8) A verification method comprising:
   constructing a surrogate model that simulates behavior of an analysis target, using operation data of the analysis target as training data;
   selecting the surrogate model that is judged to best reproduce the behavior of the analysis target by the operation data according to verification contents, under specified condition, from the operation data of the analysis target; and
   verifying the analysis target using the selected surrogate model.
(Supplementary note 9) The verification method according to Supplementary note 8, wherein the surrogate model is constructed for each domain unit, which is the smallest unit of verification.
(Supplementary note 10) A program storage medium storing a verification program wherein
   the verification program causes a computer to execute:
   a surrogate model construction process of constructing a surrogate model that simulates behavior of an analysis target, using operation data of the analysis target as training data;
   a surrogate model selection process of selecting the surrogate model that is judged to best reproduce the behavior of the analysis target by the operation data according to verification contents, under specified condition, from the operation data of the analysis target; and
   a verification process of verifying the analysis target using the selected surrogate model.
(Supplementary note 11) The program storage medium storing the verification program according to Supplementary note 10, wherein, the surrogate model is constructed for each domain unit, which is the smallest unit of verification in the surrogate model construction process.
(Supplementary note 12) A verification program wherein
   the verification program causes a computer to execute:
   a surrogate model construction process of constructing a surrogate model that simulates behavior of an analysis target, using operation data of the analysis target as training data;
   a surrogate model selection process of selecting the surrogate model that is judged to best reproduce the behavior of the analysis target by the operation data according to verification contents, under specified condition, from the operation data of the analysis target; and
   a verification process of verifying the analysis target using the selected surrogate model.
(Supplementary note 13) The verification program according to Supplementary note 12, wherein, the surrogate model is constructed for each domain unit, which is the smallest unit of verification in the surrogate model construction process.
(Supplementary note 14) A verification device comprising:
   a surrogate model storage means which stores a surrogate model that simulates behavior of an analysis target, the surrogate model being constructed using operation data of the analysis target as training data;
   a surrogate model selection means which selects the surrogate model that is judged to best reproduce the behavior of the analysis target by the operation data according to verification contents, under specified condition, from the operation data of the analysis target; and
   a verification means which verifies the analysis target using the selected surrogate model.

Although the present invention has been explained above with reference to the exemplary embodiments, the present invention is not limited to the above exemplary embodiments. Various changes can be made to the configuration and details of the present invention that can be understood by those skilled in the art within the scope of the present invention.

### REFERENCE SIGNS LIST

10 Data acquisition unit
20 Data storage unit
30 Surrogate model construction unit
40 Surrogate model storage unit
50 Surrogate model evaluation unit
60, 61, 62 Surrogate model selection unit
70 Output device
170, 270, 370 Verification unit
171 Operation verification unit
172 Simulator operation unit
271 Defect reproduction unit
272 Defect estimation unit
371 Operation verification unit
372 Simulator operation verification unit
100, 200, 300 Verification system

What is claimed is:

1. A verification system comprising:
a memory storing instructions; and
one or more processors configured to execute the instructions to:
construct a surrogate model that simulates behavior of an analysis target, using operation data of the analysis target as training data;
select the surrogate model that is judged to best reproduce the behavior of the analysis target by the operation data according to verification contents, under specified condition, from the operation data of the analysis target; and
verify the analysis target using the selected surrogate model.

2. The verification system according to claim 1, wherein the
the surrogate model construction means constructs the surrogate model for each domain unit, which is the smallest unit of verification.

3. The verification system according to claim 1, wherein the processor is configured to execute the instructions to construct the surrogate model for each domain unit that groups units by automobile function.

4. The verification system according to claim 1, wherein the processor is configured to execute the instructions to:
input the operation data including a parameter used in operating the analysis target, apply the input parameters to the selected surrogate model to calculate an evaluation value, and identify the optimal parameters as a verification result based on the calculated evaluation value; and
apply the obtained verification result to a simulator for the analysis target to obtain operating result.

5. The verification system according to claim 1, wherein the processor is configured to execute the instructions to:
input data at time of a defect, including a parameter when the defect occurred in the analysis target, and apply the input parameter to the selected surrogate model to calculate a first evaluation value; and
apply data under the normal condition to the surrogate model to calculate a second evaluation value, and compare the first evaluation value with the second evaluation value to estimate a part of the defect.

6. The verification system according to claim 1, wherein the processor is configured to execute the instructions to:
input evaluation data including a parameter under normal conditions of the analysis target, and apply the input parameter to the selected surrogate model to calculate an evaluation value; and
verify, when a defect is estimated to occur based on the evaluation value, the operation using a simulator for the analysis target for an estimated part of the defect.

7. The verification system according to claim 1, wherein the processor is configured to execute the instructions to select the surrogate model that matches a data item to be analyzed and an input/output data item.

8. A verification method comprising:
constructing a surrogate model that simulates behavior of an analysis target, using operation data of the analysis target as training data;
selecting the surrogate model that is judged to best reproduce the behavior of the analysis target by the operation data according to verification contents, under specified condition, from the operation data of the analysis target; and
verifying the analysis target using the selected surrogate model.

9. The verification method according to claim 8, wherein the surrogate model is constructed for each domain unit, which is the smallest unit of verification.

10. A non-transitory computer readable information recording medium storing a verification program, when executed by a processor, the data management program that performs a method for:
constructing a surrogate model that simulates behavior of an analysis target, using operation data of the analysis target as training data;
selecting the surrogate model that is judged to best reproduce the behavior of the analysis target by the operation data according to verification contents, under specified condition, from the operation data of the analysis target; and
verifying the analysis target using the selected surrogate model.

11. The non-transitory computer readable information recording medium according to claim 10, wherein, the surrogate model is constructed for each domain unit, which is the smallest unit of verification in the surrogate model construction process.
